(19) United States
(12) Patent Application Publication
(10) Pub. No.: US 2017/0290138 A1
(43) Pub. Date: Oct. 5, 2017

(54) PRINTED CIRCUIT BOARD

(71) Applicant: Unlimiter MFA Co., Ltd., Eden Island, SC (US)

(72) Inventors: Kuo-Ping YANG, Taipei (TW); Neo Bob Chih-Yung YOUNG, Taipei (TW); Lin-He CHU, Taipei (TW); Wen-Chiang WU, Taipei (TW); Shih-Kang HUANG, Taipei (TW); Yi-Yen CHIANG, Taipei (TW)

(21) Appl. No.: 15/437,470

(22) Filed: Feb. 21, 2017

(30) Foreign Application Priority Data
Mar. 31, 2016 (TW) 105110402

(51) Int. Cl. H05K 1/02; H05K 1/09; H05K 1/18

(52) U.S. Cl. CPC H05K 1/0203; H05K 1/181; H05K 1/09; H05K 2201/09063; H05K 2201/10636

(57) ABSTRACT

A printed circuit board has a copper clad laminate and a plurality of holes. The copper clad laminate for dissipating heats generated from a chip when the chip operates has a plurality of solder paste disposed areas. The plurality of holes situate on the copper clad laminate and each of the holes does not communicate with others, wherein the plurality of holes are nonconductors. Each of the solder paste disposed areas is surrounded by the plurality of holes and each solder paste disposed areas is surrounded by at least two holes.

### BACKGROUND OF THE INVENTION

### 1. Field of the Invention

The present invention relates to a printed circuit board (PCB), particularly to a printed circuit board having a copper clad laminate with a plurality of holes for improving the contact yield of solder paste.

### 2. Description of the Related Art

With the rapid development of electronic devices and consumer demand for electronic products to be high performance and compact and slim, the requirement for dissipating heats from a chip within an electronic device is also growing. The Surface Mount Technology is a method of soldering an electronic chip to a printed circuit board. Hereafter, a QFN (Quad Flat No-leads) chip is used as an example. To achieve good thermal efficiency, the thermal pad area of QFN chip is large. In other words, the pad area that needs to be placed on such chip is large. However, in the process of surface mount technology, if the pad area is too large, the solder paste may collapse in the heating process. That is, the solder paste is melted in liquid form and flows, resulting in not only the position offset of the chip to be soldered above the solder paste, but also insufficient amount of solder on the chip, thereby reducing the process yield of the chip within the printed circuit board. Accordingly, there is a need for improvement.

### SUMMARY OF THE INVENTION

It is a major objective of the present invention to provide a printed circuit board having a copper clad laminate with a plurality of holes by which the contact yield of solder paste in the printed circuit board can be improved.

To achieve the above objective, the printed circuit board of the present invention includes a copper clad laminate and a plurality of holes. The copper clad laminate is used for dissipating heats generated from a chip. The copper clad laminate includes a plurality of solder paste disposed areas. The plurality of holes situate on the copper clad laminate. Each of the holes does not communicate with others, wherein the plurality of holes are nonconductors. Each of the solder paste disposed areas is surrounded by the plurality of holes and each of the solder paste disposed areas is surrounded by at least two holes.

### BRIEF DESCRIPTION OF THE DRAWINGS

FIG. 1 is a schematic diagram of a printed circuit board according to an embodiment of the present invention;

FIGS. 2A to 2D show different representations regarding solder paste disposed areas surrounded by holes; and

FIGS. 3A and 3B are cross sectional views before and after the printed circuit board of the present invention being mounted to a chip.

### DETAILED DESCRIPTION OF THE PREFERRED EMBODIMENT

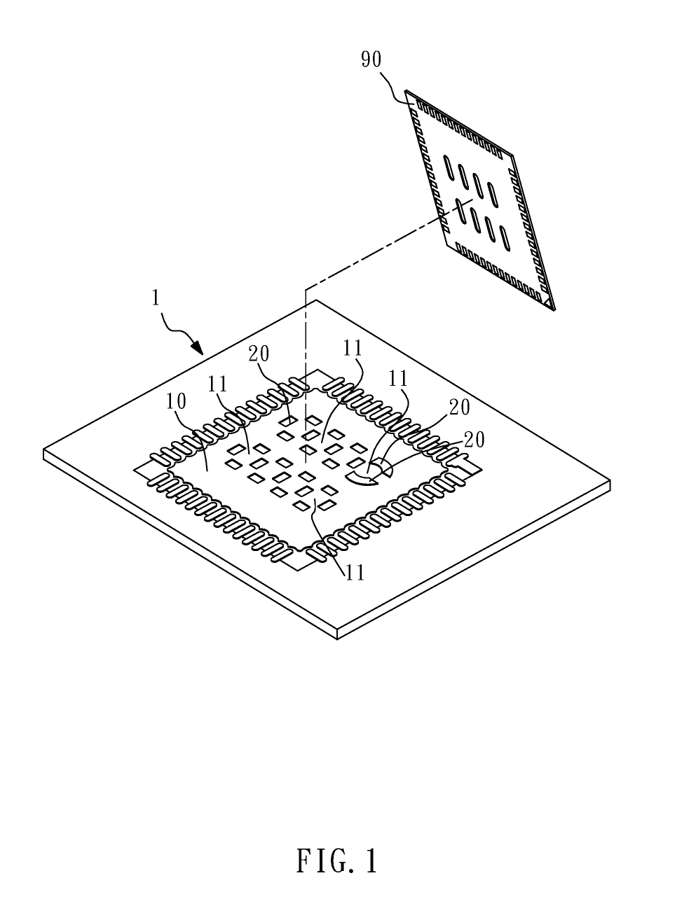

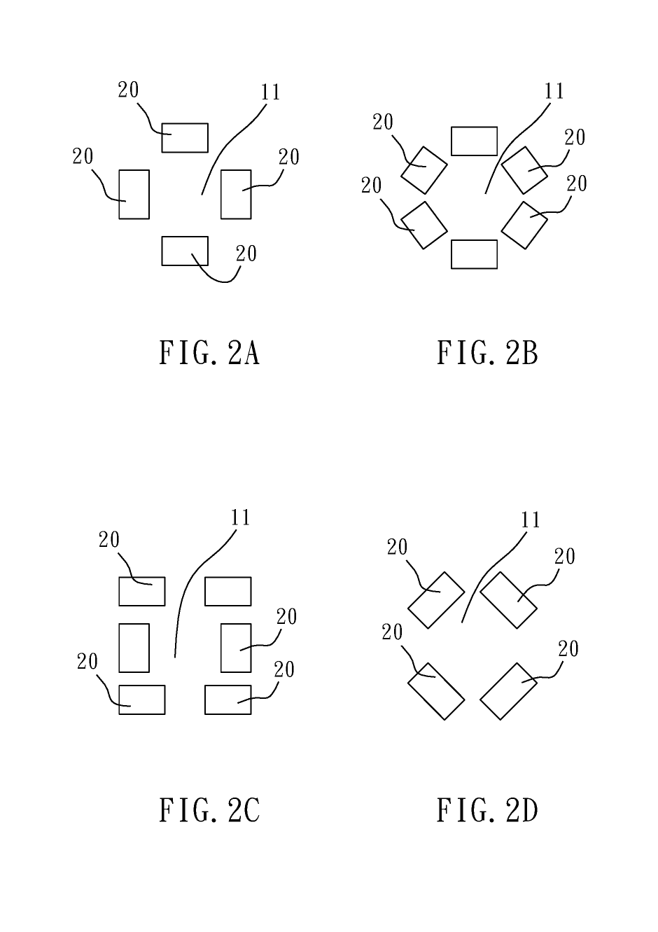

Hereafter, the technical content of the present invention will be better understood with reference to preferred embodiments. Please refer to FIG. 1 which is a schematic diagram of a printed circuit board in an embodiment of the present invention and FIGS. 2A to 2D which show different representations regarding solder paste disposed areas surrounded by a plurality of holes.

As shown in FIG. 1, the printed circuit board 1 of the present invention includes a copper clad laminate 10 and a plurality of holes 20, wherein the plurality of holes 20 situate on the copper clad laminate 10, such that the copper clad laminate 10 can be mounted to a chip 90 through a Surface Mount Technology. In the present embodiment, the copper clad laminate 10 is a thermal plate of a QFN (Quad Flat No-leads) chip. The chip 90 is a QFN chip, but the present invention is not limited thereto. The chip 90 can also be other types of chips. The holes 20 are nonconductors, wherein each of the holes 20 does not communicate with others.

As shown in FIG. 1, in the present embodiment, the copper clad laminate 10 includes a plurality of solder paste disposed areas 11. The plurality of holes 20 are dispersedly arranged around the plurality of solder paste disposed areas 11. The plurality of solder paste disposed areas 11 are solder joints of thermal pads for the QFN (Quad Flat No-leads) chip. In the present embodiment, each of the solder paste disposed areas 11 are surrounded by at least two holes 20a. As shown in FIG. 1, each of the solder paste disposed areas 11 from a top view looks like a rectangle, and the holes 20 are dispersed in each side of the rectangle. Each of the holes 20 has a gap therebetween, such that the solder paste disposed areas 11 are in communication with the copper clad laminate 10 through the gap, but the present invention is not limited thereto. Actually, as shown in FIG. 2A to FIG. 2D, the solder paste disposed areas 11 from a top view may look like any geometric shape, such as round, triangle, or polygonal shape. The plurality of holes 20 are dispersed around the plurality of sides in the geometric shape, and each of the holes 20 are not in communication with each other, such that the solder paste disposed areas 11 can be in communication with the copper clad laminate 10 through the gap. It should be noted here that the number of the solder paste disposed areas 11 in the present embodiment is 8, and the solder paste disposed areas 11 are arranged in parallel in four rows on the copper clad laminate 10, but the present invention is not limited thereto. The number and arrangement of the solder paste disposed areas 11 vary depending on the design of the chip 90. In addition, the shape of the holes 20 is not particularly limited. The holes 20 may be of other geometries, such as an arc shown as the holes 20a in FIG. 1.

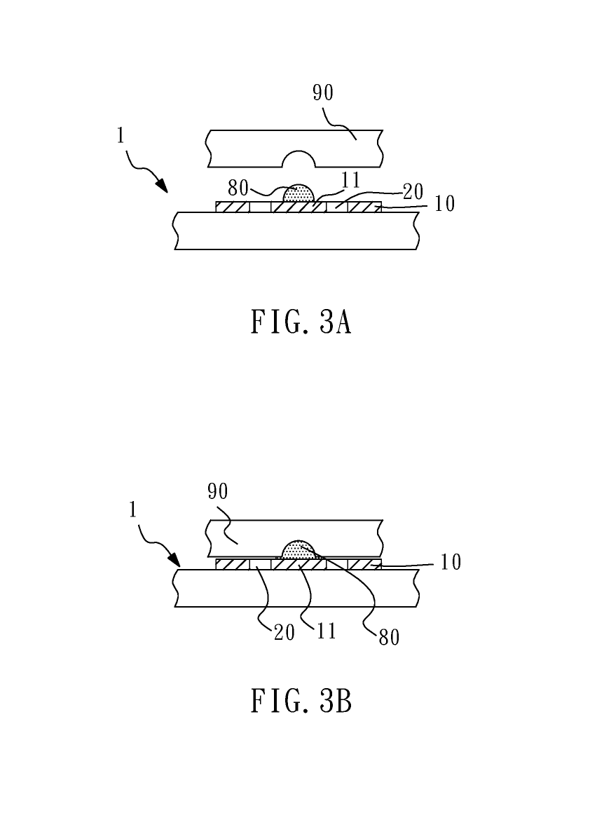

Hereafter, please still refer to FIG. 1. Also refer to FIGS. 3A and 3B which are cross sectional views before and after the printed circuit board being mounted to a chip.

As shown in FIGS. 3A and 3B, when the surface mount technology is processed, the solder paste 80 situates on the solder paste disposed areas 11. Through the design that the holes 20 situate on the copper clad laminate 10, the solder paste 80 is limited onto the solder paste disposed areas 11. The solder paste 80 will not collapse when heated, which increases the contact yield between the chip 90 and the copper clad laminate 10 when the solder paste 80 is in contact with the chip 90. According to an embodiment of the present invention, when the surface mount technology is implemented, a fixture having a plurality of circular openings may be placed on the copper clad laminate 10, where the circular openings correspond to the respective solder paste disposed areas 11, to facilitate the placement of the solder paste 80 in the solder paste disposed areas 11. The solder paste 80 is kept in a spherical shape as shown in FIGS. 3A and 3B so that the solder paste 80 does not collapse when heated, and thus the contact yield between the chip 90 and the copper clad laminate 10 can be improved.

Through the design that the holes 20 situate on the copper clad laminate 10 in the present invention, the position of the solder paste 80 is limited to the solder paste disposed areas 11, such that in the process of the surface mount technology to the printed circuit board 1, the amount of sufficient solder of the chip 90 is increased, and the contact yield between the chip 90 and the copper clad laminate 10 is improved.

It should be noted that the described embodiments are only for illustrative and exemplary, and that various changes and modifications may be made to the described embodiments without departing from the scope of the invention as disposed by the appended claims.

What is claimed is:

1. A printed circuit board, for being mounted to a chip, the printed circuit board comprising:
a copper clad laminate, used for dissipating heats generated from a chip, the copper clad laminate comprising a plurality of solder paste disposed areas; and
a plurality of holes, which situate on the copper clad laminate, each of the holes does not communicate with others, wherein the plurality of holes are nonconductors, the plurality of solder paste disposed areas being surrounded by the plurality of holes, and each of the solder paste disposed areas being surrounded by at least two holes.

2. The printed circuit board as claimed in claim 1, wherein each of the solder paste disposed areas from a top view looks like a geometric shape.

3. The printed circuit board as claimed in claim 2, wherein each of the holes is dispersed around the plurality of sides in a geometric shape.

4. The printed circuit board as claimed in claim 2, wherein the geometry is circular, triangular, rectangular, or polygonal.

5. The printed circuit board as claimed in claim 4, wherein each of the holes is in a rectangular, circular, or curved shape.

6. The printed circuit board as claimed in claim 3, wherein the geometry is circular, triangular, rectangular, or polygonal.

7. The printed circuit board as claimed in claim 6, wherein each of the holes is in a rectangular, circular, or curved shape.

8. The printed circuit board as claimed in claim 1, wherein each of the plurality of holes is spaced by a gap from each other, and each of the solder paste disposed areas is in communication with the copper clad laminate through the gap.

9. The printed circuit board as claimed in claim 8, wherein each of the solder paste disposed areas from a top view looks like a geometric shape.

10. The printed circuit board as claimed in claim 9, wherein the geometry is circular, triangular, rectangular, or polygonal.

11. The printed circuit board as claimed in claim 9, wherein each of the holes is dispersed around the plurality of sides in a geometric shape.

12. The printed circuit board as claimed in claim 11, wherein the geometry is circular, triangular, rectangular, or polygonal.

13. The printed circuit board as claimed in claim 1, wherein the copper clad laminate 10 is a thermal plate of a QFN (Quad Flat No-leads) chip.
